(19) United States
(12) Patent Application Publication
(10) Pub. No.: US 2024/0162209 A1
(43) Pub. Date: May 16, 2024

(54) LIGHT EMITTING MODULE WITH INTEGRATED LAMP AND DRIVER AND DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventor: Li ZHONG, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 18/194,452

(22) Filed: Mar. 31, 2023

(30) Foreign Application Priority Data
Nov. 14, 2022 (CN) 202211425359.4

(51) Int. Cl. H01L 25/16; H01L 33/54; H01L 33/58; H01L 33/62

(52) U.S. Cl. CPC H01L 25/167; H01L 33/54; H01L 33/58; H01L 33/62

(57) ABSTRACT

A light emitting module with integrated lamp and driver includes a substrate, a driving circuit layer disposed on the substrate, a bonding electrode disposed on a side of the substrate away from the driving circuit layer, an insulating layer disposed on a side of the driving circuit layer away from the substrate, a second electrode disposed on a side of the insulating layer away from the substrate and electrically connected to the driving circuit layer, a light emitting layer electrically connected to a side of the second electrode away from the substrate, and a plurality of driving chips arranged in the driving circuit layer. The driving circuit layer includes at least one first electrode disposed on a side close to the substrate. The bonding electrode penetrates through the substrate and is electrically connected to a corresponding first electrode. The driving chips are configured to drive the light emitting layer.

### CROSS-REFERENCE TO RELATED APPLICATIONS

This application claims priority to Chinese Patent Application No. 202211425359.4, filed with the Chinese Patent Office on Nov. 14, 2022, and entitled “LIGHT EMITTING MODULE WITH INTEGRATED LAMP AND DRIVER AND DISPLAY DEVICE”. The entire disclosures of the above application are incorporated herein by reference.

### TECHNICAL FIELD

The present application relates to the field of display technology, in particular to a light emitting module with integrated lamp and driver and a display device.

### BACKGROUND

With the maturity of flat-panel display technology, many display companies have invested in the development of next-generation displays. Light emitting diode (full name in English: light emitting diode, referred to as LED) has gradually become a research hotspot in the display industry due to its advantages such as good reliability, small size, and high brightness. In the display industry, since the small-pitch RGB LED direct display can bring an excellent visual experience, the market share continues to grow. Active drive (AM) has gradually become a research hotspot in the industry because it is suitable for high-resolution (PPI), high-brightness, and high-transmittance applications.

Currently, there are two main ways to implement AM driving: One is a single-pixel R/G/B LED driven by a silicon-based microchip (Si—OC). That is, the microchip and RGB LED are bound to the passive drive (PM) wiring substrate by bonding to realize the electrical connection between the LED and the drive circuit. The other is to stamp R/G/B LEDs on the active drive (AM) substrate to realize the electrical connection between the LED and the drive circuit.

For the microchip active drive scheme, the microchip can simplify the peripheral drive circuit and realize PWM drive, so it has a great application prospect in the fields of RGB LED direct display and backlight. The current mainstream solution uses silicon-based complementary metal-oxide-semiconductor (English full name: Complementary Metal-Oxide-Semiconductor, CMOS for short) to drive microchips. Due to the limited size of the wafer and the limited number of microchips cut out, the resolution of the display screen is getting higher and higher. Since each pixel needs to use a microchip, the cost of the microchip is also greatly increased. In addition, the existing LED driver integrated package is usually packaged after the microchip and RGB LED are bonded to a package carrier, which is not conducive to the integration and miniaturization of the package.

### SUMMARY

The purpose of the present invention is to provide a light emitting module with integrated lamp and driver and a display device, which can solve issues in the prior art that the number of cut microchips is limited due to the limited size of the wafer, the cost of the microchip is high, and the integration and miniaturization of the lamp-driver package cannot be integrated and miniaturized.

In order to solve the above issues, the present invention provides a light emitting module with integrated lamp and driver comprising: a substrate; a driving circuit layer disposed on the substrate, wherein the driving circuit layer comprises at least one first electrode disposed on a side close to the substrate; a bonding electrode disposed on a side of the substrate away from the driving circuit layer, wherein the bonding electrode penetrates through the substrate and is electrically connected to a corresponding first electrode; an insulating layer disposed on a side of the driving circuit layer away from the substrate; a second electrode disposed on a side of the insulating layer away from the substrate and electrically connected to the driving circuit layer; a light emitting layer electrically connected to a side of the second electrode away from the substrate; and a plurality of driving chips arranged in the driving circuit layer, wherein the driving chips are configured to drive the light emitting layer.

Further, the driving chip comprises at least one of a light emitting layer driving circuit, a data latch circuit, a data shaping circuit, a data forwarding circuit, and a pulse width modulation circuit.

Further, a signal transmitted by the bonding electrode comprises at least one of a power signal, a data input signal, a data output signal, and a ground signal.

Further, the light emitting module with integrated lamp and driver further comprises a first encapsulation layer surrounding the light emitting layer and extending over the insulating layer, the driving circuit layer, and the substrate; and a second encapsulation layer covering a side of the light emitting layer away from the substrate and extending to cover the first encapsulation layer.

Further, a refractive index of the first encapsulation layer is less than 5%, and a material of the first encapsulation layer comprises one or more of a black epoxy resin, a black silica gel, and a black photoresist; a surface of the first encapsulation layer disposed on a side away from the substrate is flush with a surface of the light emitting layer disposed on a side away from the substrate.

Further, a refractive index of the first encapsulation layer is greater than 90%, and a material of the first encapsulation layer comprises a white ink.

Further, the light emitting module with integrated lamp and driver further comprises a bonding area and a bond area; the first electrode layer is located in the bonding area; the light emitting layer is located within the bond area; a projection of the bond area on the driving circuit layer is outside a projection of the bonding area on the driving circuit layer; or the projection of the bond area on the driving circuit layer coincides with the projection of the bonding area on the driving circuit layer.

Further, the light emitting layer comprises at least one light emitting unit, and each light emitting unit comprises at least two light emitting chips with different colors.

Further, the light emitting chip comprises one or more of submillimeter light emitting diodes and micron light emitting diodes.

In order to solve the above issues, the present invention provides a display device comprising a circuit board and a light emitting module with integrated lamp and driver. The light emitting module with integrated lamp and driver is electrically connected to the circuit board through the bonding electrode.

The advantages of the present invention are that: In the present invention, a driving circuit layer is arranged on the substrate, and a plurality of driving chips are arranged in the driving circuit layer, and the driving chips are used to drive the light emitting layer. The side of the driving circuit layer away from the substrate is electrically connected to the light emitting layer, the side of the substrate away from the driving circuit layer is provided with a bonding electrode, and the bonding electrode penetrates through the substrate and is electrically connected to the driving circuit layer. In this way, issues such as the limited number of cut microchips and the high cost of microchips caused by the limited wafer size in the prior art of using silicon-based CMOS to drive microchips are avoided.

In the present invention, the first encapsulation layer and the second encapsulation layer are prepared on the same substrate. The driving circuit layer and the light emitting layer are encapsulated by the first encapsulation layer and the second encapsulation layer, without an additional encapsulation substrate. This reduces the process complexity of the first encapsulation layer and the second encapsulation layer, and improves the integration of the first encapsulation layer and the second encapsulation layer. This is beneficial to miniaturization and thinning of the first encapsulation layer and the second encapsulation layer.

### BRIEF DESCRIPTION OF THE DRAWINGS

In order to more clearly illustrate the technical solutions in the embodiments of the present application, the following briefly introduces the drawings that need to be used in the description of the embodiments. Apparently, the drawings in the following description are only some embodiments of the present application. For those skilled in the art, other drawings can also be obtained based on these drawings without any creative effort.

FIG. 1 is a schematic structural diagram of a display device according to Embodiment 1 of the present invention.

FIG. 2 is a schematic plan view of a light emitting module with integrated lamp and driver according to Embodiment 1 of the present invention.

FIG. 3 is a partial structural schematic diagram of a light emitting module with integrated lamp and driver according to Embodiment 1 of the present invention.

FIG. 4 is a schematic structural diagram of a display device according to Embodiment 2 of the present invention.

FIG. 5 is a partial structural schematic diagram of a light emitting module with integrated lamp and driver according to Embodiment 2 of the present invention.

### EXPLANATION OF REFERENCE SIGNS

1000: Display device; 100: Light emitting module with integrated lamp and driver.
200: Circuit board.
1: Substrate; 2: Driving circuit layer.
3: Bonding electrode; 4: Insulating layer.
5: Second electrode; 6: Light emitting layer.
7: First encapsulation layer; 8: Second encapsulation layer.
9: Third electrode; 21: First electrode.
61: Light emitting unit; 62: Light emitting functional layer.
63: Light emitting chip electrode.
611: First light emitting chip.
612: Second light emitting chip; 613: Third light emitting chip.

### DETAILED DESCRIPTION OF ILLUSTRATED EMBODIMENTS

Preferred embodiments of the present invention will be described in detail below in conjunction with the accompanying drawings, so as to fully introduce the technical content of the present invention to those skilled in the art. Examples are used to prove that the present invention can be implemented, so that the technical content disclosed in the present invention is clearer, and it is easier for those skilled in the art to understand how to implement the present invention. However, the invention can be embodied in many different forms of embodiment. The protection scope of the present invention is not limited to the embodiments mentioned herein, and the description of the following embodiments is not intended to limit the scope of the present invention.

The directional terms mentioned in the present invention, such as “up”, “down”, “front”, “back”, “left”, “right”, “inside”, “outside”, “side”, etc., are only appended direction in the figure. The directional terms used herein are used to explain and illustrate the present invention, rather than to limit the protection scope of the present invention.

In the drawings, components with the same structure are denoted by the same numerals, and components with similar structures or functions are denoted by similar numerals. In addition, for ease of understanding and description, the size and thickness of each component shown in the drawings are arbitrarily shown, and the present invention does not limit the size and thickness of each component.

### Embodiment 1

This embodiment provides a display device 1000. The display device includes a circuit board 200 and at least one light emitting module with integrated lamp and driver 100.

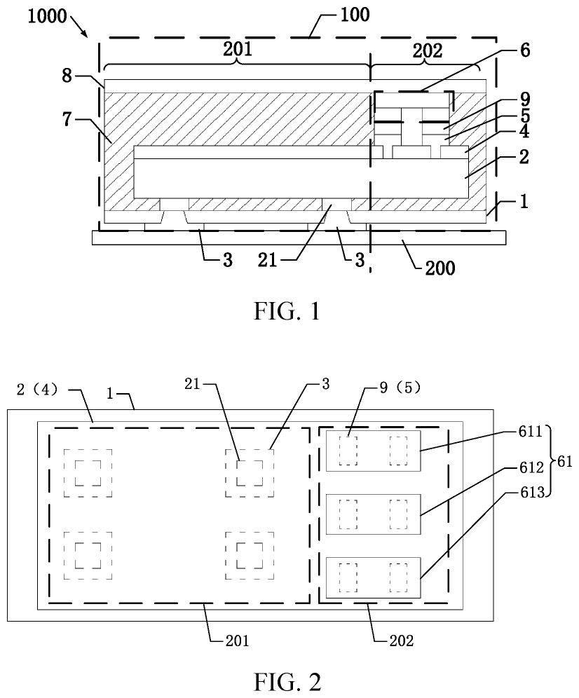

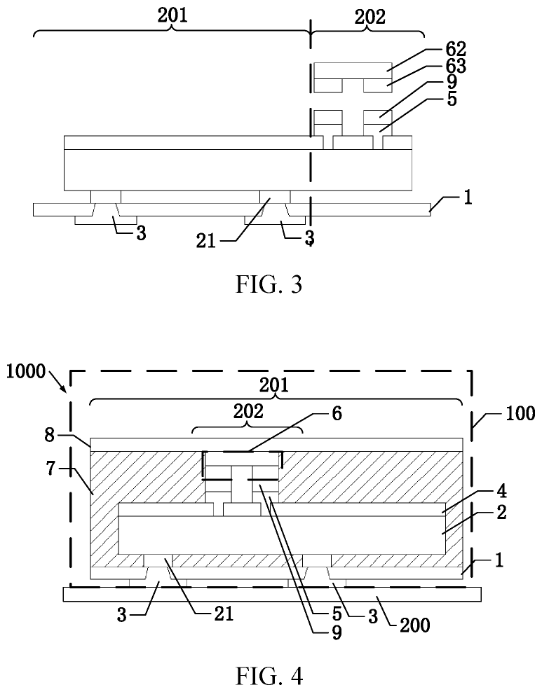

As shown in FIG. 1, FIG. 2, and FIG. 3, the light emitting module with integrated lamp and driver 100 includes: a substrate 1, a driving circuit layer 2, a bonding electrode 3, an insulating layer 4, a second electrode 5, a light emitting layer 6, a first encapsulation layer 7, a second encapsulation layer 8, and a third electrode 9.

The material of the substrate 1 includes one or more of glass, polyimide, polycarbonate, polyethylene terephthalate, and polyethylene naphthalate. In this embodiment, the material of the substrate 1 is polyimide, which is convenient for forming through holes on the substrate later. This enables the bonding electrode 3 to be electrically connected to the first electrode 21 through the through hole, thereby realizing the electrical connection between the bonding electrode 3 and the driving circuit layer 2.

Specifically, through holes may be formed on the substrate 1 by a laser drilling process or a photolithography process.

The driving circuit layer 2 is disposed on the substrate 1. A plurality of driving chips are arranged in the driving circuit layer 2, and the driving chips are used to drive the light emitting layer 6. The driving chip includes at least one of a light-emitting layer driving circuit, a data latch circuit, a data shaping circuit, a data forwarding circuit, and a pulse width modulation (English full name: Pulse Width Modulation, PWM for short) circuit.

The side of the driving circuit layer 2 close to the substrate 1 has at least one first electrode 21. The first electrode 21 is mainly used for electrically connecting the bonding electrode 3 and the driving circuit layer 2.

The bonding electrode 3 is disposed on a side of the substrate 1 away from the driving circuit layer 2, and the bonding electrode 3 penetrates through the substrate 1 and is electrically connected to the corresponding first electrode 21. The bonding electrode 3 may be a material conducive to bonding prepared by processes such as electroplating, electroless plating, and vapor deposition. The material of the bonding electrode 3 is for example, copper (Cu), tin (Sn), etc. The light emitting module with integrated lamp and driver 100 is electrically connected to the circuit board 200 through the bonding electrodes 3.

The signals transmitted by the bonding electrodes 3 include: at least one of a power signal, a data input signal, a data output signal, and a ground signal. In other embodiments, the bonding electrodes 3 can also be used to transmit other signals, so as to realize the continuous transmission function of the driving circuit layer 2.

The insulating layer 4 is disposed on the side of the driving circuit layer 2 away from the substrate 1 and mainly protects the driving circuit layer 2.

The second electrode 5 is disposed on a side of the insulating layer 4 away from the substrate 1 and electrically connected to the driving circuit layer 2. The second electrode 5 is mainly used to electrically connect the driving circuit layer 2 and the light emitting layer 6.

The third electrodes 9 are electrically connected to the side of the second electrode 5 away from the substrate 1 in one-to-one correspondence, for electrically connecting the second electrode 5 and the light emitting layer 6. Since the melting point of the second electrode 5 is relatively high, it cannot be welded, electroplating, electroless plating, evaporation and other processes are used to prepare a material that is conducive to welding, such as copper (Cu), tin (Sn), etc.

The light emitting layer 6 is electrically connected to the side of the third electrode 9 away from the substrate 1. The light emitting layer 6 includes at least one light emitting unit 61, and each light emitting unit 61 includes at least two light emitting chips with different colors. In this embodiment, the light emitting layer 6 includes a light emitting unit 61, and the light emitting unit 61 includes a first light emitting chip 611, a second light emitting chip 612, and a third light emitting chip 613 with different colors. Specifically, the first light emitting chip 611, the second light emitting chip 612, and the third light emitting chip 613 are respectively one of a red light emitting chip, a green light emitting chip, and a blue light emitting chip. In this embodiment, the first light emitting chip 611 is a red light emitting chip, the second light emitting chip 612 is a green light emitting chip, and the third light emitting chip 613 is a blue light emitting chip. The light emitting chips in each light emitting unit 61 can be connected in series, in parallel or in combination according to actual needs.

The light emitting chip includes one or more of submillimeter light emitting diodes (Mini LEDs) and micron light emitting diodes (Micro LEDs). Since the size of the Micro LED is less than 30 μm, compared with the Mini-LED, using the Micro LED as the light emitting chip can further reduce the package size of the light emitting module with integrated lamp and driver 100, and reduce the production cost.

Each of the light emitting chips includes a light emitting functional layer 62 and a light emitting chip electrode 63 located between the light emitting functional layer 62 and the third electrode 9. Specifically, each of the light emitting chips has two light emitting chip electrodes 63, and the two light emitting chip electrodes 63 are respectively an anode and a cathode for electrically connecting to the third electrode 9.

The first encapsulation layer 7 surrounds the light emitting layer 6 and extends to cover the insulating layer 4, the driving circuit layer 2, and the substrate 1. It is mainly used to prevent water and oxygen from invading the driving circuit layer 2.

The refractive index of the first encapsulation layer 7 is less than 5%, and the material of the first encapsulation layer 7 includes one or more of a black epoxy resin, a black silica gel, and a black photoresist. In this way, the reflectivity of the first encapsulation layer 7 of the light emitting module with integrated lamp and driver 100 can be reduced, light crosstalk between adjacent light emitting chips can be prevented, and the integrated black effect can be increased. This is beneficial to improve the contrast of the light emitting module with integrated lamp and driver 100, and further makes the light emitting module with integrated lamp and driver 100 applied to a direct display device. In this embodiment, the material of the first encapsulation layer 7 is black epoxy resin. The surface of the first encapsulation layer 7 away from the substrate 1 is flush with the surface of the light emitting layer 6 away from the substrate 1. This prevents the first encapsulation layer 7 from covering the light emitting layer 6, which facilitates light emission from the light emitting layer 6.

In other embodiments, the refractive index of the first encapsulation layer 7 is greater than 90%, and the material of the first encapsulation layer 7 includes white ink. In this way, the light emitting module with integrated lamp and driver 100 can be applied to the backlight module, the reflectivity of the first encapsulation layer 7 of the light emitting module with integrated lamp and driver 100 can be improved, and the light extraction efficiency of the backlight module can be improved.

The second encapsulation layer 8 covers the side of the light emitting layer 6 away from the substrate 1 and extends to cover the first encapsulation layer 7 to further prevent water and oxygen from corroding the driving circuit layer 2 and the light emitting layer 6.

The second encapsulation layer 8 is made of a transparent or translucent material, and the transmittance range of the second encapsulation layer 8 is above 40%. Users can adjust the transmittance of the second encapsulation layer 8 according to different application scenarios.

As shown in FIG. 2, the driving circuit layer 2 includes a bonding area 201 and a bond area 202. The first electrode layer 21 is located in the bonding area 201. The light emitting layer 6 is located in the bond area 202. In this embodiment, the projection of the bond area 202 on the driving circuit layer 2 is outside the projection of the bonding area 201 on the driving circuit layer 2.

To sum up, by disposing the driving circuit layer 2 on the substrate 1, a plurality of driving chips are arranged in the driving circuit layer 2, and the driving chips are used to drive the light emitting layer 6. The side of the driving circuit layer 2 away from the substrate 1 is electrically connected to the light emitting layer 6, and the side of the substrate 1 away from the driving circuit layer 2 is provided with a bonding electrode 3, and the bonding electrode 3 penetrates the substrate 1 and is electrically connected to the driving circuit layer 2. In this way, issues such as the limited number of cut microchips and the high cost of microchips caused by the limited wafer size in the prior art of using silicon-based CMOS to drive microchips are avoided.

In this embodiment, the first encapsulation layer 7 and the second encapsulation layer 8 are prepared on the same substrate 1. The driving circuit layer 2 and the light emitting layer 6 are encapsulated by the first encapsulation layer 7 and the second encapsulation layer 8 without an additional encapsulation substrate. This reduces the process complexity of the first encapsulation layer 7 and the second encapsulation layer 8 and improves the integration of the first encapsulation layer 7 and the second encapsulation layer 8. This is beneficial to miniaturization and thinning of the first encapsulation layer 7 and the second encapsulation layer 8.

### Embodiment 2

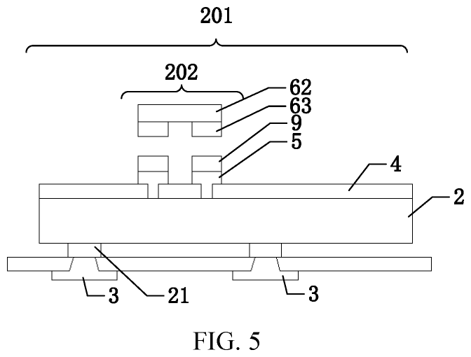

As shown in FIG. 4 and FIG. 5, this embodiment includes most of the technical features of Embodiment 1. The difference between this embodiment and embodiment 1 is that: In this embodiment, the projection of the bond area 202 on the driving circuit layer 2 coincides with the projection of the bonding area 201 on the driving circuit layer 2. Specifically, the projection of the bond area 202 on the driving circuit layer 2 falls within the projection of the bonding area 201 on the driving circuit layer 2. Therefore, the size of the light emitting module with integrated lamp and driver 100 can be reduced, which is beneficial for application in high-resolution (PPI) display devices.

Furthermore, the light emitting module with integrated lamp and driver and the display device provided by the present application have been introduced in detail above. In this disclosure, specific examples are used to illustrate the principles and implementation methods of the present application. The descriptions of the above embodiments are only used to help understand the method and the core idea of the present application. In addition, for those skilled in the art, there may be changes in specific implementation methods and application scopes based on the idea of the present application. To sum up, the contents of this specification should not be understood as limiting the application.

What is claimed is:

1. A light emitting module with integrated lamp and driver, comprising:
a substrate;
a driving circuit layer disposed on the substrate, wherein the driving circuit layer comprises at least one first electrode disposed on a side close to the substrate;
a bonding electrode disposed on a side of the substrate away from the driving circuit layer, wherein the bonding electrode penetrates through the substrate and is electrically connected to a corresponding first electrode;
an insulating layer disposed on a side of the driving circuit layer away from the substrate;
a second electrode disposed on a side of the insulating layer away from the substrate and electrically connected to the driving circuit layer;
a light emitting layer electrically connected to a side of the second electrode away from the substrate; and
a plurality of driving chips arranged in the driving circuit layer, wherein the driving chips are configured to drive the light emitting layer.

2. The light emitting module with integrated lamp and driver according to claim 1, wherein the driving chip comprises at least one of a light emitting layer driving circuit, a data latch circuit, a data shaping circuit, a data forwarding circuit, and a pulse width modulation circuit.

3. The light emitting module with integrated lamp and driver according to claim 2, wherein a signal transmitted by the bonding electrode comprises at least one of a power signal, a data input signal, a data output signal, and a ground signal.

4. The light emitting module with integrated lamp and driver according to claim 3, further comprising:
a first encapsulation layer surrounding the light emitting layer and extending over the insulating layer, the driving circuit layer, and the substrate; and
a second encapsulation layer covering a side of the light emitting layer away from the substrate and extending to cover the first encapsulation layer.

5. The light emitting module with integrated lamp and driver according to claim 4, wherein a refractive index of the first encapsulation layer is less than 5%, and a material of the first encapsulation layer comprises one or more of a black epoxy resin, a black silica gel, and a black photoresist;
wherein a surface of the first encapsulation layer disposed on a side away from the substrate is flush with a surface of the light emitting layer disposed on a side away from the substrate.

6. The light emitting module with integrated lamp and driver according to claim 4, wherein a refractive index of the first encapsulation layer is greater than 90%, and a material of the first encapsulation layer comprises a white ink.

7. The light emitting module with integrated lamp and driver according to claim 1, further comprising:
a bonding area and a bond area;
wherein the first electrode layer is located in the bonding area;
wherein the light emitting layer is located within the bond area;
wherein a projection of the bond area on the driving circuit layer is outside a projection of the bonding area on the driving circuit layer; or
wherein the projection of the bond area on the driving circuit layer coincides with the projection of the bonding area on the driving circuit layer.

8. The light emitting module with integrated lamp and driver according to claim 1, wherein the light emitting layer comprises at least one light emitting unit, and each light emitting unit comprises at least two light emitting chips with different colors.

9. The light emitting module with integrated lamp and driver according to claim 8, wherein the light emitting chip comprises one or more of submillimeter light emitting diodes and micron light emitting diodes.

10. A display device, comprising:
a circuit board and a light emitting module with integrated lamp and driver, wherein the light emitting module with integrated lamp and driver comprises:
a substrate;
a driving circuit layer disposed on the substrate, wherein the driving circuit layer comprises at least one first electrode disposed on a side close to the substrate;
a bonding electrode disposed on a side of the substrate away from the driving circuit layer, wherein the bonding electrode penetrates through the substrate and is electrically connected to a corresponding first electrode;
an insulating layer disposed on a side of the driving circuit layer away from the substrate;
a second electrode disposed on a side of the insulating layer away from the substrate and electrically connected to the driving circuit layer;
a light emitting layer electrically connected to a side of the second electrode away from the substrate; and
a plurality of driving chips arranged in the driving circuit layer, wherein the driving chips are configured to drive the light emitting layer;
wherein the light emitting module with integrated lamp and driver is electrically connected to the circuit board through the bonding electrode.

11. The display device according to claim 10, wherein the driving chip comprises at least one of a light emitting layer driving circuit, a data latch circuit, a data shaping circuit, a data forwarding circuit, and a pulse width modulation circuit.

12. The display device according to claim 11, wherein a signal transmitted by the bonding electrode comprises at least one of a power signal, a data input signal, a data output signal, and a ground signal.

13. The display device according to claim 12, further comprising:
a first encapsulation layer surrounding the light emitting layer and extending over the insulating layer, the driving circuit layer, and the substrate; and
a second encapsulation layer covering a side of the light emitting layer away from the substrate and extending to cover the first encapsulation layer.

14. The display device according to claim 13, wherein a refractive index of the first encapsulation layer is less than 5%, and a material of the first encapsulation layer comprises one or more of a black epoxy resin, a black silica gel, and a black photoresist;
wherein a surface of the first encapsulation layer disposed on a side away from the substrate is flush with a surface of the light emitting layer disposed on a side away from the substrate.

15. The display device according to claim 13, wherein a refractive index of the first encapsulation layer is greater than 90%, and a material of the first encapsulation layer comprises a white ink.

16. The display device according to claim 10, further comprising:
a bond area and a bonding area;
wherein the first electrode layer is located in the bond area;
wherein the light emitting layer is located within the bonding area;
wherein a projection of the bonding area on the driving circuit layer is outside a projection of the bond area on the driving circuit layer; or
wherein the projection of the bonding area on the driving circuit layer coincides with the projection of the bond area on the driving circuit layer.

17. The display device according to claim 10, wherein the light emitting layer comprises at least one light emitting unit, and each light emitting unit comprises at least two light emitting chips with different colors.

18. The display device according to claim 17, wherein the light emitting chip comprises one or more of submillimeter light emitting diodes and micron light emitting diodes.
